(19) United States
(12) Patent Application Publication
(10) Pub. No.: US 2013/0334678 A1
(43) Pub. Date: Dec. 19, 2013

(54) DEVICE FOR SUPPORTING A SUBSTRATE, AS WELL AS METHODS FOR MANUFACTURING AND USING SUCH A DEVICE

(71) Applicant: Xycarb Ceramics B.V., Helmond (NL)

(72) Inventors: Willem Pieter Van Duijn, Helmond (NL); Carolus Wilhelmus Pas, Helmond (NL)

(21) Appl. No.: 13/907,525

(22) Filed: May 31, 2013

Related U.S. Application Data
(62) Division of application No. 11/919,324, filed on Oct. 25, 2007, now abandoned.

(30) Foreign Application Priority Data
Apr. 26, 2005 (NL) 1028867

(51) Int. Cl. H01L 21/683; H01L 21/306

(52) U.S. Cl. CPC H01L 21/683; H01L 21/306
USPC 257/734; 216/56; 438/706

(57) ABSTRACT

A device (10) supports a substrate during the manufacture of semiconductor components. The device includes a substantially flat plate with an upper surface (11) on which the substrate can be positioned. In some embodiments, the device (10) is of inexpensive and simple construction and allows for the passage of a process gas in the direction of the substrate under certain manufacturing conditions, for example for supplying a protective gas to the substrate or having the substrate rest on an air cushion. The upper surface (11) of the plate is at least partially porous (14). Thus, costly and extremely precise machining of the device (10), as usually required in the current state of the art, is unnecessary, thereby making it possible to manufacture the device (10) at much lower cost.

### CROSS REFERENCE TO RELATED APPLICATIONS

The present application is a division of U.S. patent application Ser. No. 11/919,324, having a 371(c) filing date of Oct. 25, 2007, incorporated herein by reference, which is the U.S. national stage of PCT application no. PCT/NL2006/000226, filed Apr. 26, 2006, incorporated herein by reference, which claims priority of the Netherlands patent application NL 1028867, filed 26 Apr. 2005.

The invention relates to a device for supporting a substrate during the manufacture of semiconductor components, comprising a substantially flat plate with an upper surface on which the substrate can be positioned.

The invention also relates to a method for manufacturing such a device.

Such a device is shown in European patent publication No. 0683505, for example. The device or susceptor described in said patent specification is provided with a pattern made up of one or more or grooves as well as openings in the upper surface thereof, through which grooves and openings a process gas can be passed under the substrate that is present on the device.

The grooves and the openings for the process gas have been machined in the upper surface, for example by means of a drilling or milling technique. This leads to a costly and, in addition, complex construction.

The object of the invention is to provide a device according to the preamble, which is of inexpensive and simple construction but which also allows the passage of a process gas in the direction of the substrate under certain manufacturing conditions, for example for supplying a protective gas to the substrate or having the substrate rest on an air cushion.

According to the invention, the upper surface of the plate is at least partially porous. Thus, costly and extremely precise machining of the device, as usually required in the current state of the art, is unnecessary, thereby making it possible to manufacture the device at much lower cost.

According to a further aspect of the device according to the invention, the upper surface contains at least partially porous metal carbide.

The porosity of the upper surface can be adjusted in that case by etching away at least metal molecules, whilst more in particular the porosity of the upper surface can also be adjusted by etching away at least metal carbide molecules.

Experiments have shown that a functional embodiment of the device can be obtained if the porosity ranges between 5 vol. % and 90 vol. %.

In a specific embodiment according to the invention, the device is made up of a composite composed of a carbon core and an outer layer of metal carbide.

More in particular, said metal carbide is silicon carbide.

According to the invention, the method for manufacturing a device for supporting a substrate during the manufacture of semiconductor components comprises at least the steps of:
A supplying a carbon core;
B applying a layer of metal carbide to the carbon core;
C making the layer of metal carbide at least partially porous by at least partially etching away metal molecules.

More specifically, the method is further characterised by the step of
D making the layer of metal carbide at least partially porous by at least partially etching away metal carbide molecules.

The invention will now be explained in more detail with reference to a drawing, in which:

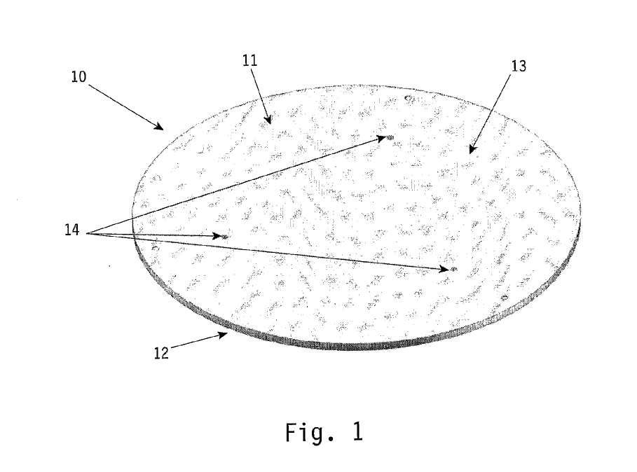

FIG. 1 is a cross-sectional view of an embodiment of a susceptor according to the invention;

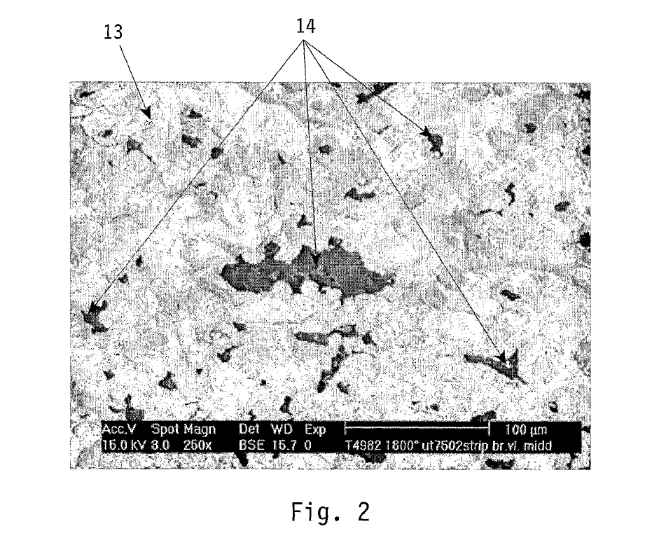

FIG. 2 is a photo that shows the material of a susceptor according to the invention prior to the etching operation for obtaining a porous structure;

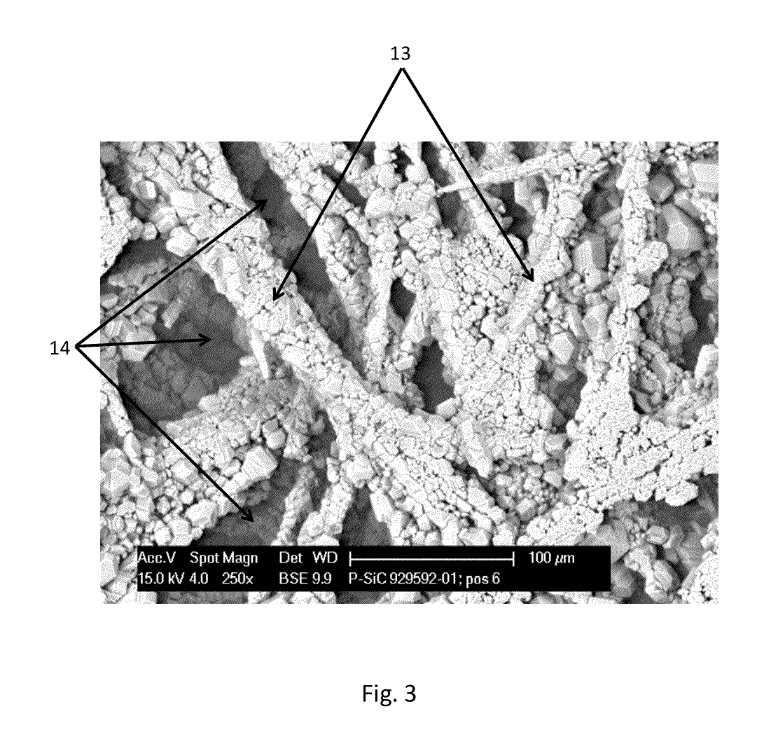

FIG. 3 is a photo that shows the material of a susceptor according to the invention after the etching operation for obtaining a porous structure.

FIG. 1 shows in top view a susceptor according to the invention. The susceptor 10 functions as a device for supporting a substrate during the manufacture of semiconductor components and comprises a substantially flat plate 10 having a lower surface 12 and an upper surface 11. The substrate is positioned on said upper surface 11 during the manufacturing steps of the semiconductor components.

The susceptor 10 is at least partially made of a metal carbide material 13, and more in particular the upper surface 11 is at least partially made of metal carbide.

According to the invention, the substrate is at least partially porous, and more in particular the upper surface 11 of the susceptor is at least partially porous. This leads to porous openings 14 obtained by etching away at least metal carbide molecules from which the upper surface 11, and more in particular the susceptor, is made. See FIGS. 2 and 3, which show the material of the susceptor according to the invention prior to and after the etching operation, respectively.

More specifically, the susceptor is made up of a composite, which is composed of a carbon core and an outer layer of metal carbide. The porosity of at least the upper surface of the susceptor can be adjusted by etching away at least metal carbide molecules or by etching away at least metal molecules.

More specifically, the porosity ranges between 5 vol. % and 90 vol. %.

The porous nature of the susceptor makes it possible to supply a process gas at the bottom side, which process gas is passed through the porous channels in the susceptor to the upper surface 11 on which the substrate (not shown) is positioned. By supplying a process gas or, for example, a protective gas to the substrate, said substrate can be positioned on an air cushion, for example, which is desirable under certain manufacturing conditions of semiconductor components.

When the susceptor according to the invention is used it is no longer necessary to subject the susceptor according to the prior art to costly and extremely precise machining operations, which operations are required with the susceptors that are currently being used in the semiconductor industry. The susceptor according to the invention is easier to manufacture, the more so because the porosity of the susceptor, and in particular of the upper surface thereof, is adjustable.

1. A method for manufacturing a device for supporting a substrate during the manufacture of semiconductor components, the method comprising:
obtaining a carbon core;
applying a layer of metal carbide to the carbon core;
making the layer of metal carbide at least partially porous by at least partially etching away metal molecules.

2. A method according to claim 2, wherein making the layer of metal carbide at least partially porous comprises at least partially etching away metal carbide molecules.

3. A method of manufacturing semiconductor components, the method comprising processing a substrate supported at an upper surface of a plate, wherein at least part of the upper surface comprises porous metal carbide;
wherein processing the substrate comprises supplying a gas from a bottom surface of the plate through the porous channels to the upper surface.

4. A method according to claim 3 wherein the gas is a process gas.

5. A method according to claim 3 wherein the process gas is a protective gas.

6. A method according to claim 3 wherein the gas forms a gas cushion on which the substrate is supported.

7. A method according to claim 3, wherein the device is a composite composed of a carbon core and an outer layer of metal carbide.

8. A method according to claim 3, wherein the porosity of the plate ranges between 5 vol. % and 90 vol. %.

9. A device according to claim 3, wherein said metal carbide is silicon carbide.
